(19) United States
(12) Patent Application Publication
(10) Pub. No.: US 2015/0070532 A1
(43) Pub. Date: Mar. 12, 2015

(54) SOLID STATE IMAGING DEVICE AND METHOD FOR MANUFACTURING THE SAME

(71) Applicant: Kabushiki Kaisha Toshiba, Minato-ku (JP)

(72) Inventors: Lisa MASUDA, Yokohama (JP); Naotada Okada, Yokohama (JP); Kazuhiro Suzuki, Minato (JP); Risako Ueno, Meguro (JP); Mitsuyoshi Kobayashi, Ota (JP); Hideyuki Funaki, Shinagawa (JP)

(73) Assignee: Kabushiki Kaisha Toshiba, Minato-ku (JP)

(21) Appl. No.: 14/481,307

(22) Filed: Sep. 9, 2014

(30) Foreign Application Priority Data
Sep. 12, 2013 (JP) 2013-189393

(51) Int. Cl. H01L 27/146; H04N 9/64; H04N 9/04

(52) U.S. Cl. CPC H01L 27/14627; H01L 27/14621; H01L 27/14685; H04N 9/045; H04N 9/646
USPC 348/234; 257/432; 438/70

(57) ABSTRACT

According to one embodiment, a solid state imaging device includes an imaging substrate unit, a lens unit, and a color filter unit. The imaging substrate unit has a major surface including first region and second regions including pixels. The lens unit is separated from the major surface in a first direction perpendicular to the major surface. The lens unit includes a first lens overlapping the pixels of the first region when projected onto the major surface and a second lens overlapping the pixels of the second region when projected onto the major surface. The color filter unit is provided between the imaging substrate unit and the lens unit and is separated from the imaging substrate unit. The color filter unit includes a first color filter provided between the first region and the first lens, and a second color filter provided between the second region and the second lens.

### CROSS-REFERENCE TO RELATED APPLICATIONS

This application is based upon and claims the benefit of priority from Japanese Patent Application No. 2013-189393, filed on Sep. 12, 2013; the entire contents of which are incorporated herein by reference.

### FIELD

Embodiments described herein relate generally to a solid sate imaging device and a method for manufacturing the same.

### BACKGROUND

High definition is desirable in a solid state imaging device such as, for example, a CMOS image sensor, a CCD image sensor, etc.

### BRIEF DESCRIPTION OF THE DRAWINGS

FIG. 1 is a schematic cross-sectional view showing a solid state imaging device according to a first embodiment;

FIG. 2 is a schematic plan view showing the solid state imaging device according to the first embodiment;

FIG. 3 is a flowchart showing operations of the solid state imaging device according to the first embodiment;

FIG. 4 is a schematic cross-sectional view showing a solid state imaging device according to the first embodiment;

FIG. 5 is a schematic cross-sectional view showing a solid state imaging device according to the first embodiment;

FIG. 6 is a schematic cross-sectional view showing a solid state imaging device according to the first embodiment;

FIG. 7 is a flowchart showing a method for manufacturing a solid state imaging device according to a second embodiment;

FIG. 8A to FIG. 8C are schematic cross-sectional views in order of the processes, showing the method for manufacturing the solid state imaging device according to the second embodiment;

FIG. 9 is a flowchart showing the method for manufacturing the solid state imaging device according to the second embodiment; and

FIG. 10A to FIG. 10C are schematic cross-sectional views in order of the processes, showing the method for manufacturing the solid state imaging device according to the second embodiment.

### DETAILED DESCRIPTION

According to one embodiment, a solid state imaging device includes an imaging substrate unit, a lens unit, and a color filter unit. The imaging substrate unit has a major surface including a first region and a second region. The first region includes a plurality of pixels, and the second region includes a plurality of pixels. The lens unit is separated from the major surface in a first direction perpendicular to the major surface. The lens unit includes a first lens and a second lens. The first lens overlaps the plurality of pixels of the first region when projected onto the major surface. The second lens overlaps the plurality of pixels of the second region when projected onto the major surface. The color filter unit is provided between the imaging substrate unit and the lens unit and is separated from the imaging substrate unit. The color filter unit includes a first color filter and a second color filter. The first color filter is provided between the first region and the first lens and has a first color. The second color filter is provided between the second region and the second lens and has a second color different from the first color.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

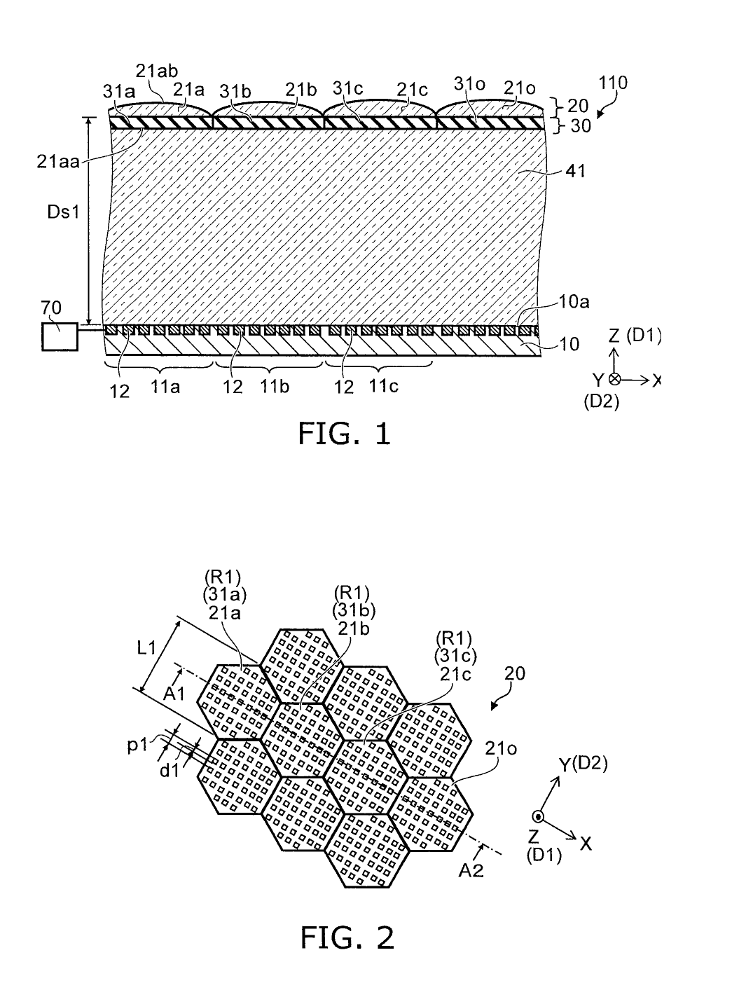

FIG. 1 is a schematic cross-sectional view showing a solid state imaging device according to a first embodiment.

FIG. 2 is a schematic plan view showing the solid state imaging device according to the first embodiment.

FIG. 1 is a cross-sectional view along line A1-A2 of FIG. 2.

As shown in FIG. 1 and FIG. 2, the solid state imaging device 110 according to the embodiment includes an imaging substrate unit 10, a lens unit 20, and a color filter unit 30.

The imaging substrate unit 10 includes multiple pixels 12. The imaging substrate unit 10 has a major surface 10a. The multiple pixels 12 are disposed in a plane parallel to the major surface 10a.

A direction perpendicular to the major surface 10a is taken as a Z-axis direction (a first direction D1). One direction perpendicular to the Z-axis direction is taken as an X-axis direction. A direction perpendicular to the Z-axis direction and the X-axis direction is taken as a Y-axis direction.

The major surface 10a includes, for example, multiple regions. The major surface 10a includes, for example, a first region 11a, a second region 11b, and a third region 11c.

The first region 11a includes the multiple pixels 12. The second region 11b includes the multiple pixels 12. The third region 11c includes the multiple pixels 12.

The pixel 12 includes, for example, a photodiode including a p-n junction. The configuration of the pixel 12 is arbitrary. The pixel 12 converts, for example, an optical signal of visible light and/or infrared light into an electrical signal. For example, a silicon substrate is used as the imaging substrate unit 10. Other than the pixels 12, a circuit unit including CMOS elements, etc., may be provided in the imaging substrate unit 10. The circuit unit may include a signal processor 70 described below.

The lens unit 20 is separated from the major surface 10a in the first direction D1. The first direction D1 (the Z-axis direction) is perpendicular to the major surface 10a. The lens unit 20 includes multiple lenses 21o (e.g., a first lens 21a, a second lens 21b, a third lens 21c, etc.).

The first lens 21a overlaps the multiple pixels 12 of the first region 11a when projected onto the major surface 10a. The second lens 21b overlaps the multiple pixels 12 of the second region 11b when projected onto the major surface 10a. The third lens 21c overlaps the multiple pixels 12 of the third region 11c when projected onto the major surface 10a.

The lenses 21o include a light-transmissive material. The lenses 21o are, for example, made of a light-transmissive resin. The resin 21o may be an acrylic resin, an epoxy resin, etc. Glass, etc., may be used as the lenses 21o.

The color filter unit 30 is provided between the imaging substrate unit 10 and the lens unit 20. The color filter unit 30 is separated from the imaging substrate unit 10. The color filter unit 30 includes multiple color filters 31o (e.g., a first color filter 31a, a second color filter 31b, a third color filter 31c, etc.).

The first color filter 31a is provided between the first region 11a and the first lens 21a. The first color filter 31a has a first color.

The second color filter 31b is provided between the second region 11b and the second lens 21b. The second color filter 31b has a second color. The second color is different from the first color.

The third color filter 31c is provided between the third region 11c and the third lens 21c. The third color filter 31c has a third color. The third color is different from the first color and different from the second color.

For example, the first color, the second color, and the third color correspond respectively to red, green, and blue. In the embodiment, the first color, the second color, and the third color are arbitrary. For example, the peak wavelength absorbed by the second color filter 31b is different from the peak wavelength absorbed by the first color filter 31a. For example, the peak wavelength absorbed by the third color filter 31c is different from the peak wavelength absorbed by the first color filter 31a and different from the peak wavelength absorbed by the second color filter 31b. For example, the peak wavelength transmitted by the second color filter 31b is different from the peak wavelength transmitted by the first color filter 31a. For example, the peak wavelength transmitted by the third color filter 31c is different from the peak wavelength transmitted by the first color filter 31a and different from the peak wavelength transmitted by the second color filter 31b.

The color filter 31o includes, for example, a resin, and a colorant dispersed in the resin. The resin may, for example, be an acrylic resin, an epoxy resin, a polyimide resin, etc. For example, a pigment, a dye, etc., is used as the colorant. The thickness (the length along the Z-axis direction) of the color filter 31o is, for example, not less than 0.5 micrometers (μm) and not more than 5 μm.

A resin layer 41 is provided in the example. The resin layer 41 is provided between the imaging substrate unit 10 and the color filter unit 30. The resin layer 41 is light-transmissive. The resin layer 41 includes an acrylic resin, an epoxy resin, etc. In the example, the refractive index of the resin layer 41 is about 1.5.

The color filter unit 30 is separated from the imaging substrate unit 10 by the resin layer 41. Thereby, the lens unit 20 also is separated from the imaging substrate unit 10.

A distance Ds1 along the first direction (the Z-axis direction) between the imaging substrate unit 10 and the lens unit 20 is, for example, not less than 10 μm and not more than 80 μm. In the example, the distance Ds1 is not less than 45 μm and not more than 55 μm (about 50 μm).

As shown in FIG. 2, the multiple lenses that are included in the lens unit 20 are disposed in a hexagonal configuration. The embodiment is not limited thereto; and the disposition and planar configuration of the multiple lenses are arbitrary.

In the example, the size of the second lens 21b is the same as the size of the first lens 21a. In the example, the size of the third lens 21c is the same as the size of the first lens 21a.

The size (the width) of the lens 21o of the lens unit 20 is larger than the size of the pixel 12. One direction perpendicular to the first direction D1 is taken as a second direction D2. The second direction D2 is parallel to the major surface 10a. In the example, the width of the lens 21o is a maximum in the second direction D2.

A lens length L1 is the length along the second direction D2 of the lens 21o (e.g., the first lens 21a). The lens length L1 is, for example, not less than 10 μm and not more than 100 μm. In the example, the lens length L1 is not less than 25 μm and not more than 35 μm (e.g., 30 μm).

On the other hand, a pixel length d1 is the length along the second direction of each of the multiple pixels 12. The pixel length d1 is, for example, not less than 0.5 μm and not more than 3 μm. In the example, the pixel length d1 is, for example, not less than 1.0 μm and not more than 1.5 μm (e.g., 1.4 μm).

A pixel pitch p1 is the pitch of the multiple pixels 12 in the second direction. The pixel pitch p1 is, for example, not less than 1 μm and not more than 5 μm. In the example, the pixel pitch p1 is, for example, not less than 2.0 μm and not more than 3.0 μm (e.g., 2.8 μm).

For example, the lens length L1 is not less than 6 times and not more than 100 times the pixel length d1. In the example, the lens length L1 is not less than 7 times and not more than 72 times the pixel length d1.

For example, the lens length L1 is not less than 3 times and not more than 50 times the pixel pitch p1.

For example, the distance Ds1 is not less than 0.5 times and not more than 5 times the lens length L1.

In the solid state imaging device 110 according to the embodiment, the light passes through the lens unit 20 and the color filter unit 30 to be incident on the pixels 12. The electrical signals obtained at the pixels 12 change according to the intensity of the light incident on the pixels 12.

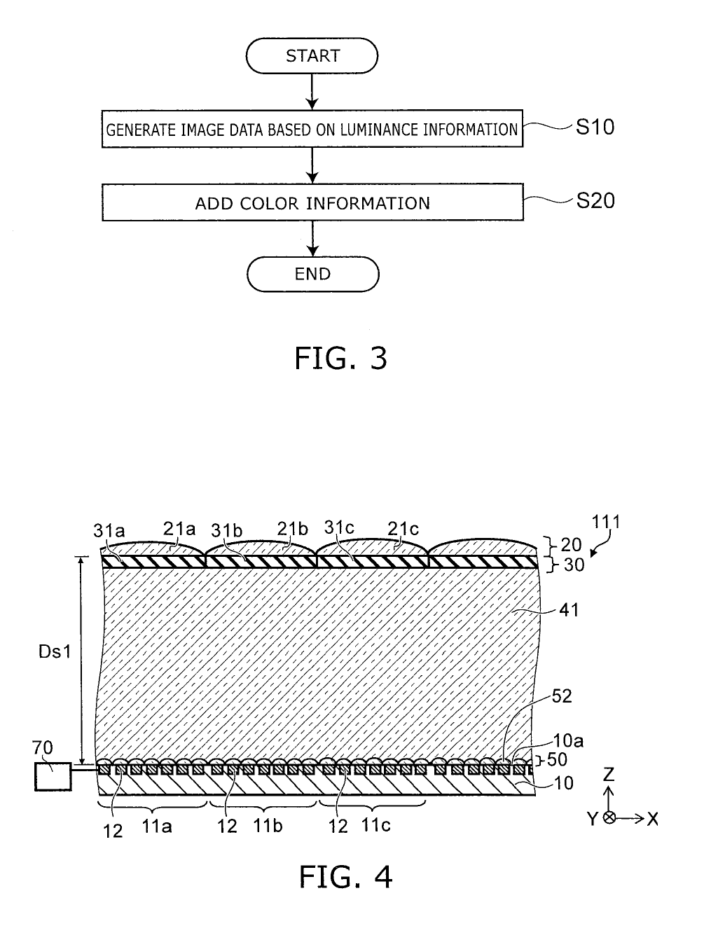

FIG. 3 is a flowchart showing operations of the solid state imaging device according to the first embodiment.

FIG. 3 shows processing implemented by the signal processor 70 (referring to FIG. 1).

As shown in FIG. 3, in the embodiment, an image is generated based on luminance information (step S10). Then, color information is added to the generated image data (step S20).

For example, the signal processor 70 implements first processing. In the first processing, the image data is generated based on the first luminance information included in the first signals obtained from the multiple pixels 12 included in the first region 11a and the second luminance information included in the second signals obtained from the multiple pixels 12 included in the second region 11b. The signal processor 70 further implements second processing. In the second processing, the color information is added to the generated image data.

For example, a reference example may be considered in which the distance information is reconfigured by deriving differences of the data corresponding to mutually-adjacent microlenses based on the luminance information and the color information. In such a case, the processing is complex because data processing relating to the color information should be performed.

Conversely, in the embodiment, first, the image data is generated by reconfiguring the distance information based on the luminance information. The color information is added subsequently. Thereby, the processing when reconfiguring is simple and advantageous.

In the solid state imaging device 110 according to the embodiment, one color filter 31o is provided to have a large surface area that includes multiple pixels 12. The effect of the error of the position of the color filter 31o on the detection signal is small.

For example, there is a reference example in which the color filters are provided to correspond respectively to the pixels 12. In such a case, the pitch of one color filter is the same as the pixel pitch. Color mixing occurs easily in the case where the positional precision of the color filters is low. The color mixing becomes pronounced as the pixels have higher definition. Accordingly, high definition is difficult in such a reference example.

On the other hand, in the embodiment, one color filter 31o is provided to have a large surface area that includes multiple pixels 12. The positional shift of the one color filter 31o for one pixel 12 is reduced. Therefore, the color mixing due to the error of the position of the color filter 31o is suppressed. In other words, in the embodiment, the color mixing does not occur easily even in the case where the pixels 12 are small. According to the embodiment, high definition is easy to obtain because the color mixing is suppressed.

In the embodiment as shown in FIG. 1, the upper surfaces of the lenses 21o have protruding configurations; and the lower surfaces of the lenses 21o are planes. In other words, the first lens 21a has a first surface 21aa and a second surface 21ab. The first surface 21aa opposes the color filter unit 30. The second surface 21ab is on the side opposite to the first surface 21aa. The first surface 21aa is parallel to the major surface 10a. The first surface 21aa is a plane. The second surface 21ab includes a portion having a curved surface.

The first surface 21aa is a plane; and the color filter 31o also has a planar configuration. The thickness of the color filter 31o is substantially uniform in the surface (in the X-Y plane). The optical characteristics (e.g., the color) of the color filter 31o can easily be set to be uniform inside the surface.

In the embodiment, the light that passes through a first portion inside the surface of one color filter 31o is incident on one of the multiple pixels 12. The light that passes through a second portion inside the surface of the one color filter 31o is incident on one other of the multiple pixels 12. The color of the light incident on the multiple pixels 12 is made uniform by increasing the uniformity of the color inside the surface of the one color filter 31o. Thereby, imaging having good color characteristics is possible.

FIG. 4 is a schematic cross-sectional view showing another solid state imaging device according to the first embodiment.

FIG. 4 is a cross-sectional view corresponding to line A1-A2 of FIG. 2.

In the solid state imaging device 111 according to the embodiment as shown in FIG. 4, a microlens unit 50 is further provided in addition to the imaging substrate unit 10, the lens unit 20, and the color filter unit 30. The microlens unit 50 is provided between the imaging substrate unit 10 and the color filter unit 30. Otherwise, the solid state imaging device 111 is similar to the solid state imaging device 110.

The microlens unit 50 includes multiple microlenses 52. The multiple microlenses 52 are disposed respectively between the color filter unit 30 and the multiple pixels 12.

In the example, the resin layer 41 is provided; and the microlens unit 50 is provided between the imaging substrate unit 10 and the resin layer 41. The multiple microlenses 52 are disposed respectively between the resin layer 41 and the multiple pixels 12.

The microlenses 52 concentrate the light onto, for example, the photosensitive portions of the pixels 12. Thereby, the sensitivity increases.

The refractive index of the multiple microlenses 52 is higher than, for example, the refractive index of the resin layer 41. Thereby, the light can be concentrated by utilizing the refraction effect of the light.

For example, the refractive index of the resin layer 41 is about 1.5. In such a case, the refractive index of the microlenses 52 is set to be higher than 1.5. For example, silicon nitride (or silicon oxynitride) or the like is used as the microlenses 52. In such a case, the refractive index of the microlenses 52 is about 2.2.

In the solid state imaging device 111 as well, a solid state imaging device in which high definition is possible can be provided. The sensitivity can be increased by providing the microlenses 52.

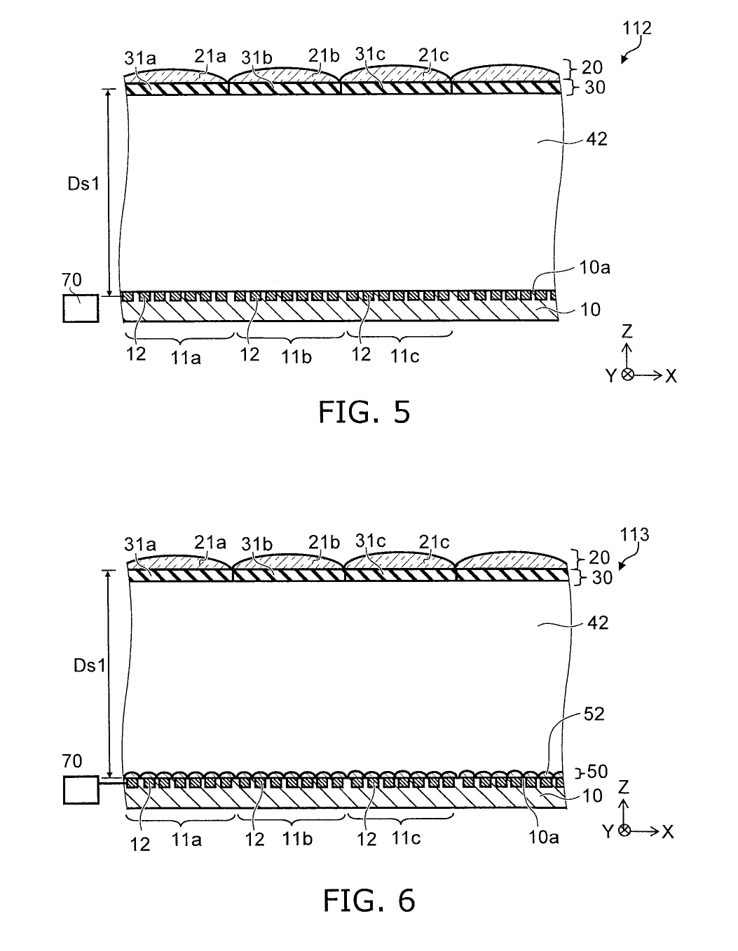

FIG. 5 is a schematic cross-sectional view showing another solid state imaging device according to the first embodiment.

FIG. 5 is a cross-sectional view corresponding to line A1-A2 of FIG. 2.

In the solid state imaging device 112 according to the embodiment as shown in FIG. 5 as well, the imaging substrate unit 10, the lens unit 20, and the color filter unit 30 are provided. In the example, the region between the imaging substrate unit 10 and the color filter unit 30 is a gap 42. Otherwise, the solid state imaging device 112 is similar to the solid state imaging device 110.

The region (the gap 42) between the imaging substrate unit 10 and the color filter unit 30 is filled with, for example, air, an inert gas, etc.

For example, the lens length L1 is about 30 μm in the example. In such a case, the distance Ds1 is about 30 μm. The distance Ds1 is, for example, not less than 25 μm and not more than 35 μm. The distance Ds1 is, for example, not less than 28 μm and not more than 32 μm.

In the solid state imaging device 112 as well, a solid state imaging device in which high definition is possible can be provided.

FIG. 6 is a schematic cross-sectional view showing another solid state imaging device according to the first embodiment.

FIG. 6 is a cross-sectional view corresponding to line A1-A2 of FIG. 2.

In the solid state imaging device 113 according to the embodiment as shown in FIG. 6, the region between the imaging substrate unit 10 and the color filter unit 30 is the gap 42. Also, the microlens unit 50 is provided. Otherwise, the solid state imaging device 113 is similar to the solid state imaging device 110.

In the solid state imaging device 113 as well, a solid state imaging device in which high definition is possible can be provided.

### Second Embodiment

The embodiment relates to a method for manufacturing a solid state imaging device.

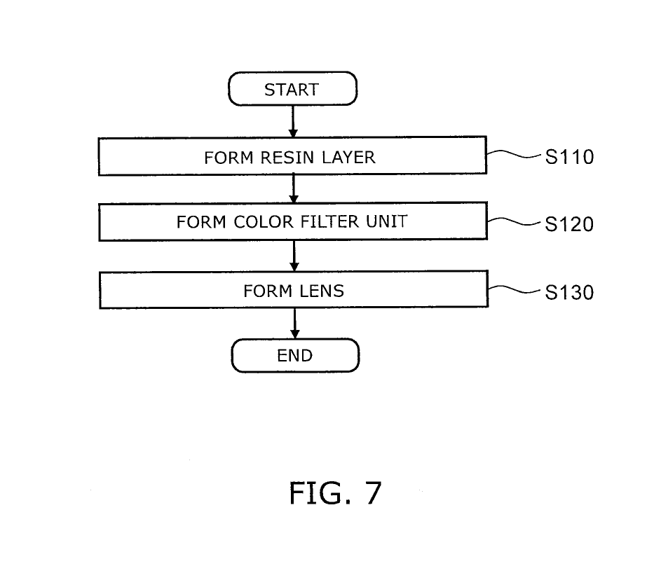

FIG. 7 is a flowchart showing the method for manufacturing the solid state imaging device according to the second embodiment.

In the manufacturing method according to the embodiment as shown in FIG. 7, the resin layer 41 is formed (step S110). Then, the color filter unit 30 is formed (step S120). Then, the lens unit 20 is formed (step S130). An example of such processing will now be described.

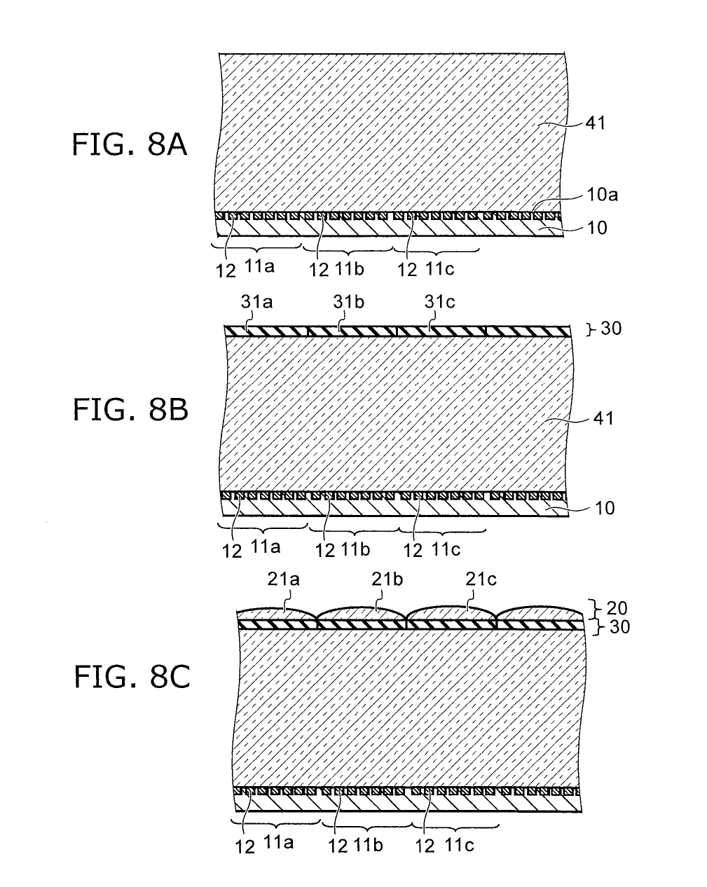

FIG. 8A to FIG. 8C are schematic cross-sectional views in order of the processes, showing the method for manufacturing the solid state imaging device according to the second embodiment.

As shown in FIG. 8A, the imaging substrate unit 10 includes the first region 11a including the multiple pixels 12, and the second region 11b including the multiple pixels 12. The resin layer 41 that is light-transmissive is formed on the major surface 10a of the imaging substrate unit 10.

As shown in FIG. 8B, the color filter unit 30 is formed on the resin layer 41. The color filter unit 30 includes the first color filter 31a and the second color filter 31b. The first color filter 31a overlaps the first region 11a when projected onto the major surface 10a. The first color filter 31a has the first color. The second color filter 31b overlaps the second region 11b when projected onto the major surface 10a. The second color filter 31b has the second color that is different from the first color.

As shown in FIG. 8C, the lens unit 20 is formed on the color filter unit 30. The lens unit 20 includes the first lens 21a and the second lens 21b. The first lens 21a overlaps the first region 11a when projected onto the major surface 10a. The second lens 21b overlaps the second region 11b when projected onto the major surface 10a.

In the manufacturing method, the color filter 31o that has a large size is formed to include the multiple pixels 12. The positional precision of the color filter 31o is relaxed; and the productivity increases.

Any method such as printing, spin coating, etc., may be used to form the resin layer 41. For example, photolithography may be used to form the resin layer 41. For example, photolithography, imprinting, etc., may be used to form the lens unit 20.

An example of the method for forming the lens unit 20 will now be described. Imprinting is used in this method.

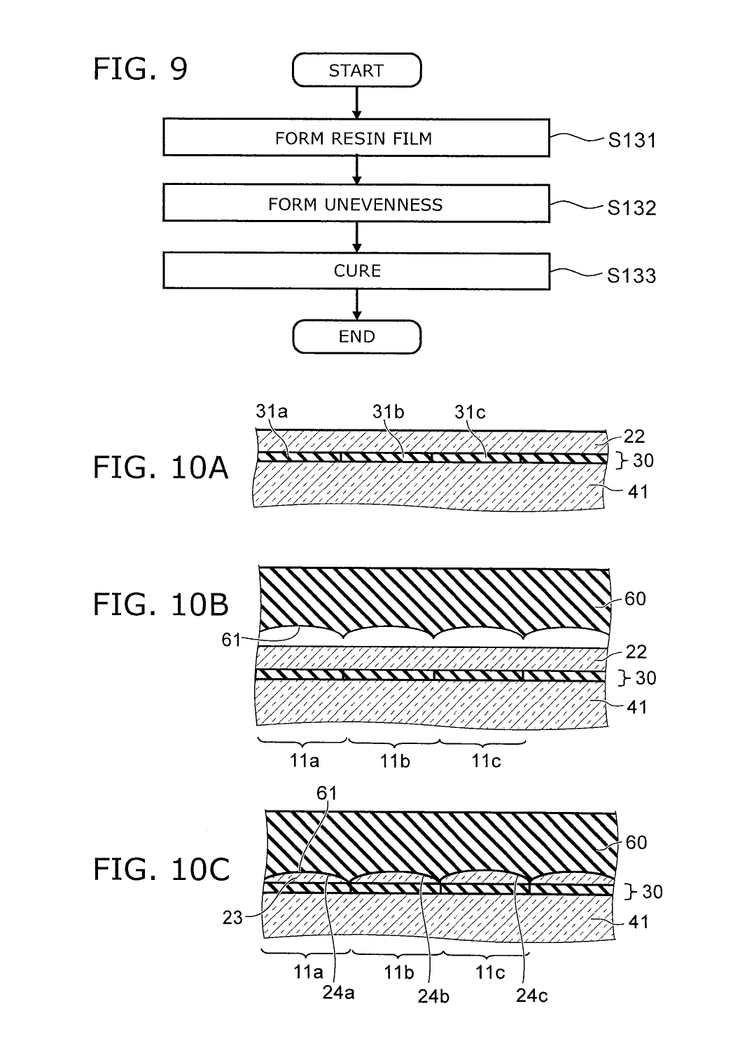

FIG. 9 is a flowchart showing the method for manufacturing the solid state imaging device according to the second embodiment.

As shown in FIG. 9, in the formation of the lens unit 20 in the manufacturing method according to the embodiment, a resin film is formed (step S131). Then, an unevenness is formed in the resin film (step S132). Then, the resin film is cured (step S133). An example of such processing will now be described.

FIG. 10A to FIG. 10C are schematic cross-sectional views in order of the processes, showing the method for manufacturing the solid state imaging device according to the second embodiment.

As shown in FIG. 10A, a resin film 22 is formed on the color filter unit 30. The resin film 22 is used to form the lenses 21o (the first lens 21a, the second lens 21b, the third lens 21c, etc.)

A mold 60 is prepared as shown in FIG. 10B. An unevenness 61 is provided in the mold 60. The configuration of the unevenness 61 corresponds to the configurations of the lenses 210 (the first lens 21a, the second lens 21b, the third lens 21c, etc.). The unevenness 61 of the mold 60 is caused to contact the resin film 22.

As shown in FIG. 10C, an unevenness 23 that reflects the unevenness 61 is formed in the surface of the resin film 22. The unevenness 23 of the resin film 22 includes a first lens-shaped unevenness 24a, a second lens-shaped unevenness 24b, a third lens-shaped unevenness 24c, etc.

The lenses 210 are formed by curing the resin film 22. In other words, the first lens 21a is formed from the first lens-shaped unevenness 24a. The second lens 21b is formed from the second lens-shaped unevenness 24b. The third lens 21c is formed from the third lens-shaped unevenness 24c.

For example, at least one selected from heating and light irradiation is implemented in the curing. The processing of the curing includes processing according to the characteristics of the resin film 22. At least a portion of the curing is performed, for example, in the state in which the unevenness 61 contacts the resin film 22. At least a portion of the curing may be performed, for example, in the state in which the unevenness 61 is separated from the resin film 22.

In the example, the formation of the lens unit 20 includes imprinting. In the embodiment, the size of the lens 21o is larger than the size of the pixel 12. Therefore, the precision is relaxed in the formation of the lens 21o. Therefore, a method having high productivity can be used.

In the embodiment, a solid state imaging device in which high definition is possible can be manufactured with high productivity.

According to the embodiments, a solid state imaging device in which high definition is possible and a method for manufacturing the solid state imaging device can be provided.

Hereinabove, embodiments of the invention are described with reference to specific examples. However, the embodiments of the invention are not limited to these specific examples. For example, one skilled in the art may similarly practice the invention by appropriately selecting specific configurations of components included in the solid state imaging device such as the imaging substrate unit, the pixel, the microlens, the color filter unit, the color filter, the lens unit, the lens, the signal processor, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all solid state imaging devices practicable by an appropriate design modification by one skilled in the art based on the solid state imaging devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

What is claimed is:

1. A solid state imaging device, comprising:
an imaging substrate unit having a major surface including a first region and a second region, the first region including a plurality of pixels, the second region including a plurality of pixels;
a lens unit separated from the major surface in a first direction perpendicular to the major surface, the lens unit including a first lens and a second lens, the first lens overlapping the plurality of pixels of the first region when projected onto the major surface, the second lens overlapping the plurality of pixels of the second region when projected onto the major surface; and
a color filter unit provided between the imaging substrate unit and the lens unit and separated from the imaging substrate unit, the color filter unit including a first color filter and a second color filter, the first color filter being provided between the first region and the first lens and having a first color, the second color filter being provided between the second region and the second lens and having a second color different from the first color.

2. The device according to claim 1, further comprising a resin layer provided between the imaging substrate unit and the color filter unit, the resin layer being light-transmissive.

3. The device according to claim 1, further comprising a microlens unit provided between the imaging substrate unit and the color filter unit, the microlens unit including a plurality of micro lenses,
each of the plurality of microlenses being disposed between the color filter unit and each of the plurality of pixels.

4. The device according to claim 1, further comprising:
a microlens unit provided between the imaging substrate unit and the color filter unit, the microlens unit including a plurality of microlenses; and
a resin layer provided between the microlens unit and the color filter unit, the resin layer being light-transmissive,
each of the plurality of microlenses being disposed between the resin layer and each of the plurality of pixels,
a refractive index of the plurality of microlenses being higher than a refractive index of the resin layer.

5. The device according to claim 1, wherein a length of the first lens along a second direction parallel to the major surface is not less than 6 times and not more than 100 times a length of each of the plurality of pixels along the second direction.

6. The device according to claim 1, wherein a distance along the first direction between the imaging substrate unit and the lens unit is not less than 0.5 times and not more than 5 times a length of the first lens along a second direction parallel to the major surface.

7. The device according to claim 1, wherein a length of the first lens along a second direction parallel to the major surface is not less than 3 times and not more than 50 times a pitch of the plurality of pixels along the second direction.

8. The device according to claim 1, wherein
the first lens has a first surface opposing the color filter unit, and a second surface on a side opposite to the first surface,
the first surface is parallel to the major surface, and
the second surface includes a portion having a curved surface.

9. The device according to claim 1, further comprising a signal processor configured to implement processing including:
first processing of generating image data based on first luminance information and second luminance information, the first luminance information being included in a first signal obtained from the plurality of pixels included in the first region, the second luminance information being included in a second signal obtained from the plurality of pixels included in the second region; and
second processing of adding color information to the generated image data.

10. The device according to claim 1, wherein
the imaging substrate unit further includes a third region provided in the major surface, the third region including the plurality of pixels,
the lens unit further includes a third lens overlapping the plurality of pixels of the third region when projected onto the major surface, and
the color filter unit further includes a third color filter provided between the third region and the third lens, the third color filter having a third color different from the first color and different from the second color.

11. The device according to claim 1, wherein a length of the first lens along the second direction is not less than 7 times and not more than 72 times a length of each of the plurality of pixels along a second direction parallel to the major surface.

12. The device according to claim 1, wherein a distance along the first direction between the imaging substrate unit and the lens unit is not less than 0.5 times and not more than 3 times a length of the first lens along a second direction parallel to the major surface.

13. The device according to claim 1, wherein
a length of the first lens along a second direction parallel to the major surface is not less than 6 times and not more than 100 times a length of each of the plurality of pixels along the second direction,
a distance along the first direction between the imaging substrate unit and the lens unit is not less than 0.5 times and not more than 5 times a length of the first lens along a second direction parallel to the major surface, and
a length of the first lens along a second direction parallel to the major surface is not less than 3 times and not more than 50 times a pitch of the plurality of pixels along the second direction.

14. The device according to claim 2, wherein the resin layer includes at least one selected from an acrylic resin and an epoxy resin.

15. The device according to claim 2, wherein the resin layer includes an acrylic resin.

16. The device according to claim 2, wherein the resin layer includes an epoxy resin.

17. The device according to claim 1, wherein a gap is provided between the imaging substrate unit and the color filter unit.

18. The device according to claim 1, further comprising a gap provided between the imaging substrate unit and the color filter unit, the gap being filled with air or an inert gas.

19. A method for manufacturing a solid state imaging device, comprising:
forming a resin layer on a major surface of an imaging substrate unit, the major surface including a first region and a second region, the first region including a plurality of pixels, the second region including a plurality of pixels, the resin layer being light-transmissive;
forming a color filter unit on the resin layer, the color filter unit including a first color filter and a second color filter, the first color filter having a first color and overlapping the first region when projected onto the major surface, the second color filter having a second color and overlapping the second region when projected onto the major surface, the second color being different from the first color; and
forming a lens unit on the color filter unit, the lens unit including a first lens and a second lens, the first lens overlapping the first region when projected onto the major surface, the second lens overlapping the second region when projected onto the major surface.

20. The method according to claim 19, wherein the forming of the lens unit includes:
forming a resin film on the color filter unit, the resin film being used to form the first lens and the second lens;
forming an unevenness in a surface of the resin film by causing a mold to contact the surface of the resin film, the unevenness reflecting an unevenness provided in the mold, the unevenness provided in the mold corresponding to configurations of the first and second lenses; and
forming the first lens and the second lens by curing the resin film.
